(19) United States
(12) Patent Application Publication
(10) Pub. No.: US 2025/0056716 A1
(43) Pub. Date: Feb. 13, 2025

(54) DISPLAY DEVICE INCLUDING PRINTED CIRCUIT BOARD

(71) Applicant: LG Display Co., Ltd., Seoul (KR)

(72) Inventor: WonTae KIM, Paju-si (KR)

(73) Assignee: LG Display Co., Ltd., Seoul (KR)

(21) Appl. No.: 18/784,189

(22) Filed: Jul. 25, 2024

(30) Foreign Application Priority Data
Aug. 11, 2023 (KR) 10-2023-0105378

(51) Int. Cl. H05K 1/02; B60K 35/22; H05K 5/00

(52) U.S. Cl. CPC H05K 1/0281; B60K 35/22; H05K 5/0069; B60K 2360/42

(57) ABSTRACT

A display device can include a display panel, and a printed circuit board connected to the display panel, in which the printed circuit board includes a plurality of elastic members positioned on different layers, the plurality of elastic members overlapping with each other, a plurality of supporting members disposed on same layers as the plurality of elastic members, respectively, and a metal layer disposed on a different layer than the plurality of elastic members and the plurality of supporting members. Also, the display device can be installed in an interior space of a vehicle.

### CROSS-REFERENCE TO RELATED APPLICATION

This application claims priority to Korean Patent Application No. 10-2023-0105378, filed in the Republic of Korea, on Aug. 11, 2023, the entirety of which is hereby incorporated by reference into the present application for all purposes as if fully set forth herein.

### BACKGROUND

### Field

The disclosure relates to a display device including a printed circuit board.

### Description of Related Art

As technology in modern society develops, display devices are used in various ways to provide information to users. Display devices include not only electronic screens that simply deliver visual information unilaterally, but also various electronic devices that use higher technology to identify the user's input and provide information in response to the identified input.

A display device can include a display panel, a driving circuit, and a controller. At least a portion of the driving circuit and/or controller can be disposed on a printed circuit board. In this situation, the printed circuit board and the display panel are coupled to each other, completing the display device. The printed circuit board and the display panel should be properly aligned when coupled to prevent deterioration of quality, such as lifting, peeling or cracking.

However, the display panel or the printed circuit board can be stretched or contracted according to various changes in the ambient environment of the display device (e.g., such a temperature, humidity, etc.). In such a situation, the display panel and the printed circuit board may become misaligned. Thus, a need arises for preventing such misalignment. Also, a need exists for a display device having a configuration that can return the display panel and the printed circuit board back to proper alignment even after having been moved due to environmental factors (e.g., temperature, humidity, vibration, etc.)

### SUMMARY OF THE DISCLOSURE

An embodiment of the disclosure provides a display device for minimizing a misalignment between a display panel and a printed circuit board using a printed circuit board including an elastic member.

However, embodiments of the disclosure are not limited thereto, and other various embodiments can be apparent to one of ordinary skill in the art from the following description.

A display device according to embodiments of the disclosure can include a display panel and a printed circuit board connected to the display panel. The printed circuit board can include a plurality of elastic members positioned on different layers and disposed to overlap with each other, a plurality of supporting members disposed on the same layer as the plurality of elastic members, respectively, and a metal layer disposed on a different layer from the plurality of elastic members and the plurality of supporting members.

A display device according to embodiments of the disclosure can include a display panel and a printed circuit board connected to the display panel, and including a first layer part and a second layer part on the first layer part. The first layer part can include a plurality of first supporting members spaced apart from each other, a first elastic member positioned between the plurality of first supporting members, and a first metal layer on the plurality of first supporting members and the first elastic member. The second layer part can include a plurality of second supporting members spaced apart from each other, a second elastic member positioned between the plurality of second supporting members, and a second metal layer on the plurality of second supporting members and the second elastic member. The first elastic member and the second elastic member can overlap with each other.

Specific details of other embodiments are included in the detailed description and

### DRAWINGS

A display device according to the disclosure can minimize a misalignment between a display panel and a printed circuit board using a printed circuit board including an elastic member.

Effects of the disclosure are not limited to the foregoing, and other unmentioned effects would be apparent to one of ordinary skill in the art from the following description.

### BRIEF DESCRIPTION OF THE DRAWINGS

The above and other objects, features, and advantages of the disclosure will be more clearly understood from the following detailed description, taken in conjunction with the accompanying drawings, in which:

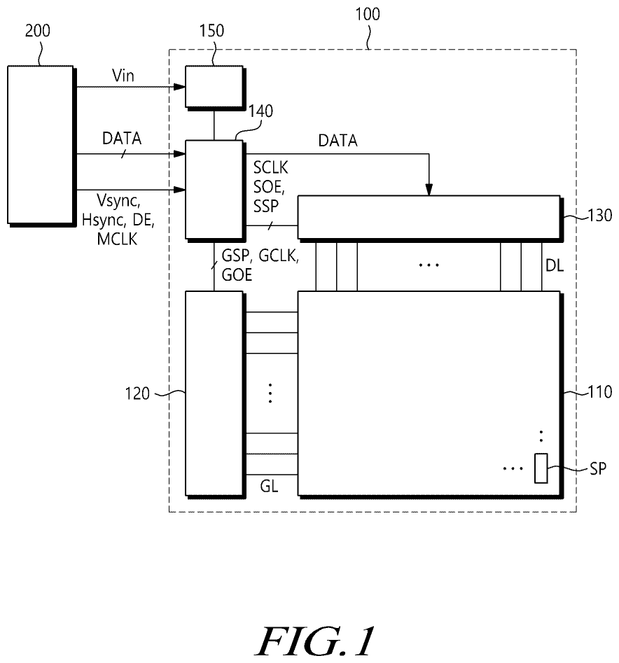

FIG. 1 is a block diagram illustrating functions of a display device according to embodiments of the disclosure;

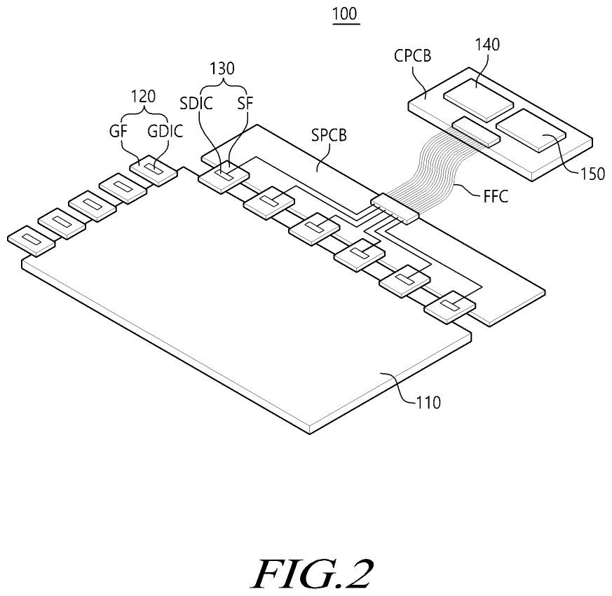

FIG. 2 is a view schematically illustrating a configuration of a display device according to embodiments of the disclosure;

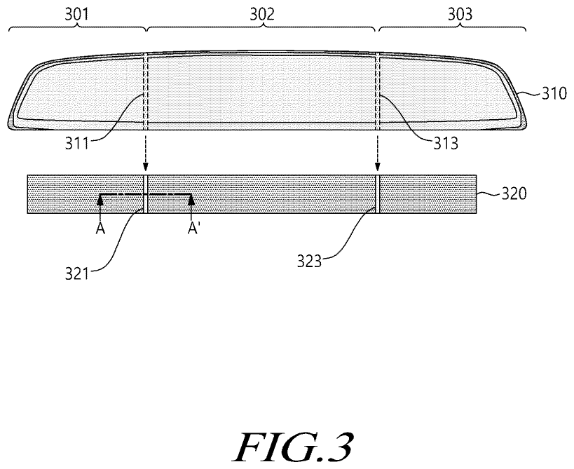

FIG. 3 is a view illustrating a display device according to embodiments of the disclosure;

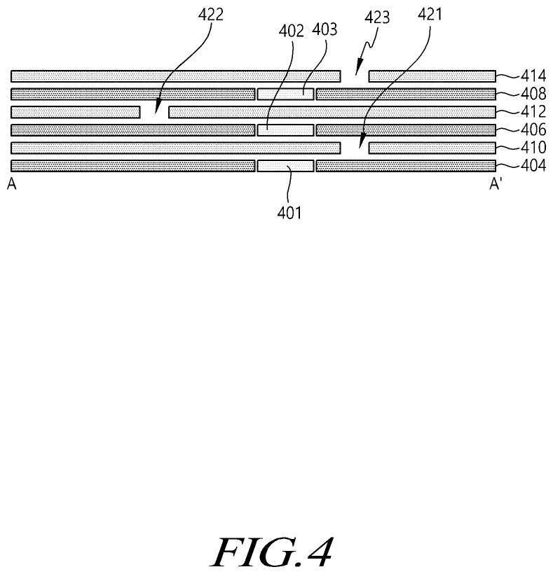

FIG. 4 is a cross-sectional view taken along line A-A′ of FIG. 3 according to an embodiment of the disclosure;

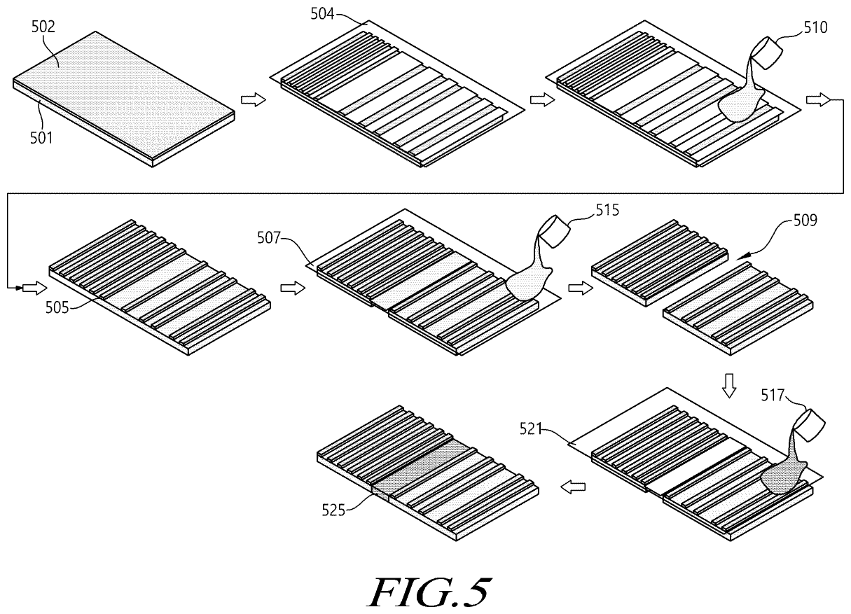

FIGS. 5, 6, and 7 are views illustrating an example method for manufacturing a printed circuit board included in a display device according to embodiments of the disclosure;

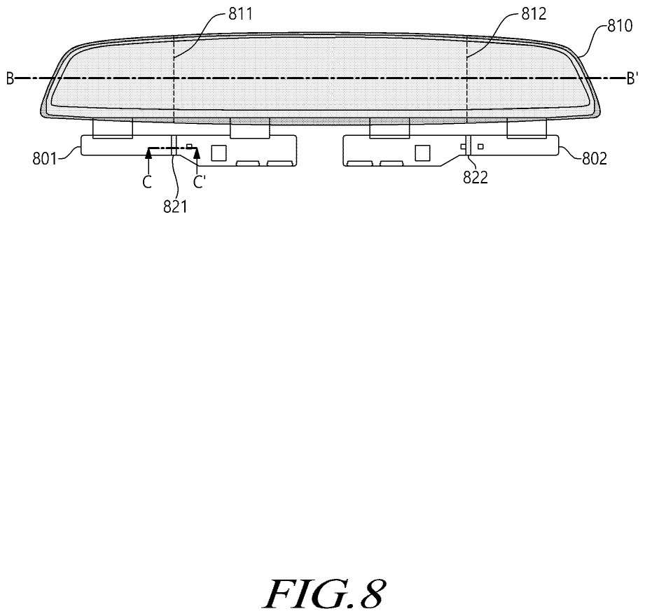

FIG. 8 is a view illustrating a display device according to another embodiment of the disclosure;

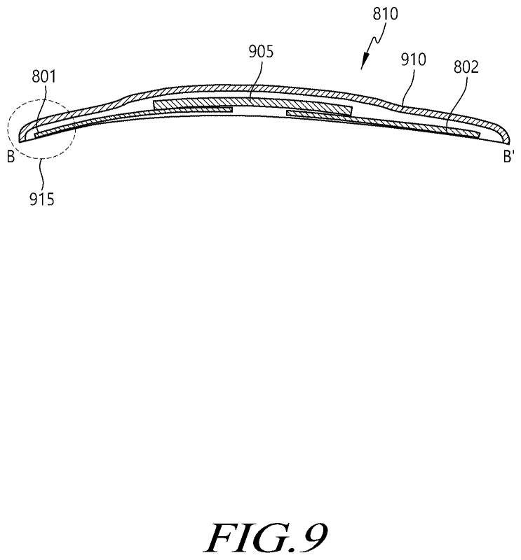

FIG. 9 is a cross-sectional view taken along line B-B′ of FIG. 8 according to an embodiment of the disclosure; and

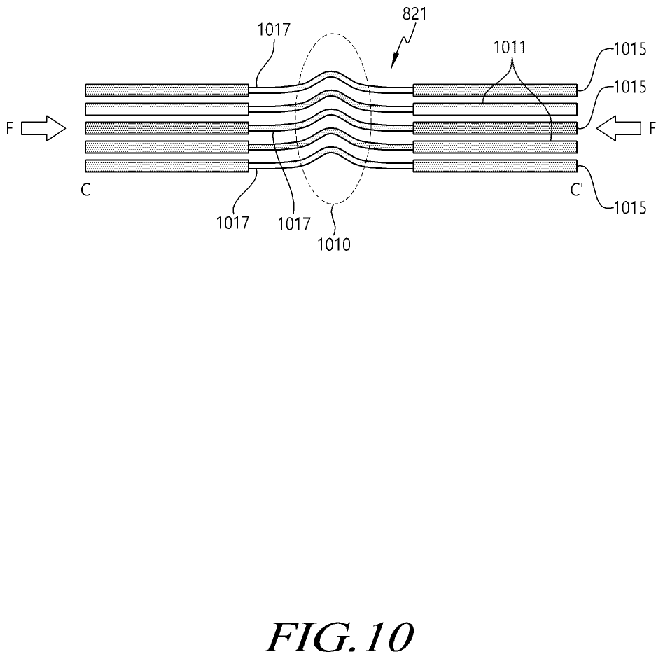

FIG. 10 is a cross-sectional view taken along line C-C′ of FIG. 8 according to an embodiment of the disclosure.

### DETAILED DESCRIPTION OF THE EMBODIMENTS

For use in embodiments of the disclosure, common terms widely used as possible have been chosen considering functions in the disclosure, but the terms can be varied depending on the intent of one of ordinary skill in the art or case laws or the advent of new technologies. In certain situations, some terms can be arbitrarily selected by the applicant, and in such situation, their detailed definitions can be given in the relevant parts thereof. Accordingly, the terms used herein should be determined based on their meanings and the overall disclosure, rather than by the terms themselves.

When an element “includes” another element, the element can further include the other element, rather excluding the other element, unless particularly stated otherwise.

As used herein, “at least one of a, b, and c” can encompass “a alone,” “b alone,” “c alone,” “a and b,” “a and c,” “b and c,” or “all of a, b, and c.” Advantages and features of the disclosure, and methods for achieving the same can be understood through the embodiments to be described below taken in conjunction with the accompanying drawings.

The shapes, areas, proportions, angles, and numbers disclosed in the drawings to illustrate embodiments of the disclosure are exemplary and are not intended to limit the disclosure to those shown. When determined to make the subject matter of the disclosure unclear, the detailed description of the known art or functions can be skipped.

As used herein, when a component “includes,” “has,” or “is composed of” another component, the component can add other components unless the component “only” includes, has, or is composed of” the other component. As used herein, the singular forms “a,” “an,” and “the” are intended to include the plural forms as well, unless the context clearly indicates otherwise. Components are interpreted to include a margin of error, even if not explicitly stated otherwise.

If the description is of a positional relationship, for example, “on,” “above,” “under,” “below,” “next to,” etc. of two parts, one or more other parts can be located between the two parts. When an element or layer is referred to as being “on” another element or layer, any layer or other element can be positioned directly on the other element or intervene therebetween.

Although the terms “first” and “second” are used to describe various components, the components are not limited by the terms. These terms are provided simply to distinguish one component from another. Accordingly, the first component mentioned herein can also be the second component within the technical spirit of the disclosure.

The area, length, and thickness of each configuration shown in the drawings are shown for illustrative purposes only, and the disclosure is not necessarily limited to the area, length, and thickness of the configurations shown.

The feature of various embodiments of the disclosure can be partially or wholly combined or coupled with each other, and various technical interlockings and operations are possible, and the embodiments can be practiced independently of each other or in conjunction with each other. Also, the term “can” includes all meanings and definitions of the term “may.”

The terms described below are ones defined considering functions in the disclosure. The terms can be varied depending on users, operators' intentions, or customs. Therefore, the terms should be defined based on the overall disclosure.

The transistor constituting the pixel circuit of the disclosure can include at least one of an oxide thin film transistor (TFT), an amorphous silicon TFT (a-Si TFT), and a low temperature polysilicon (LTPS) TFT.

The description of the following embodiments focuses primarily on an organic light emitting display device. However, embodiments of the disclosure are not limited to organic light emitting display devices but can be applied to inorganic light emitting display devices including inorganic light emitting materials. For example, embodiments of the disclosure can also be applied to quantum dot display devices.

The terms “first,” “second,” and “third” are used to distinguish components in each embodiment, but the disclosure is not limited by the terms. Therefore, it should be noted that the same term can denote different components according to embodiments.

Hereinafter, embodiments of the disclosure are described with reference to the drawings. All the components of each display device according to all embodiments of the present disclosure are operatively coupled and configured.

FIG. 1 is a block diagram illustrating functions of a display device according to embodiments of the disclosure.

Referring to FIG. 1, a display device 100 according to embodiments of the disclosure can include a display panel 110 where a plurality of gate lines GL and data lines DL are connected, and a plurality of subpixels SP are arranged in a matrix form, a gate driving circuit 120 driving the plurality of gate lines GL, a data driving circuit 130 supplying a data voltage through the plurality of data lines DL, a timing controller 140 controlling the gate driving circuit 120 and the data driving circuit 130, and a power management circuit 150.

The display panel 110 displays an image based on a scan signal transferred from the gate driving circuit 120 through the plurality of gate lines GL and the data voltage transferred from the data driving circuit 130 through the plurality of data lines DL.

In the situation of an organic light emitting display, the display panel 110 can be implemented in a top emission scheme, a bottom emission scheme, or a dual-emission scheme.

In the display panel 110, a plurality of pixels can be arranged in a matrix form, and each pixel can include subpixels SP having different colors, e.g., a white subpixel, a red subpixel, a green subpixel, and a blue subpixel, and each subpixel SP can be defined by the plurality of data lines DL and the plurality of gate lines GL.

One subpixel SP can include, e.g., a thin film transistor (TFT) formed at the intersection between one data line DL and one gate line GL, a light emitting element, such as an organic light emitting diode, charged with the data voltage, and a storage capacitor electrically connected to the light emitting element to maintain the voltage.

For example, when the display device 100 having a resolution of 2,160×3,840 includes four subpixels SP of white (W), red (R), green (G), and blue (B), 3,840 data lines DL and 2,160 gate lines GL can be connected to the pixels each having four subpixels WRGB, and thus, there can be provided 3,840×4=15,360 data lines DL. Each subpixel SP is disposed at the intersection between the gate line GL and the data line DL.

The gate driving circuit 120 can be controlled by the controller 140 to sequentially output scan signals to the plurality of gate lines GL disposed in the display panel 110, controlling the driving timing of the plurality of subpixels SP.

The gate driving circuit 120 can include one or more gate driving integrated circuits (GDICs). Depending on driving schemes, the gate driving circuit 120 can be positioned on only one side, or each of two opposite sides, of the display panel 110. The gate driving circuit 120 can be implemented in a gate-in-panel (GIP) form which is embedded in the bezel area of the display panel 110.

The data driving circuit 130 receives image data DATA from the controller 140 and convert the received image data DATA into an analog data voltage. Then, as the data voltage is output to each data line DL according to the timing when the scan signal is applied through the gate line GL, each subpixel SP connected to the data line DL displays a brightness corresponding to the data voltage.

Likewise, the data driving circuit 130 can include one or more source driving integrated circuits SDIC, and the source driving integrated circuit SDIC can be connected to the bonding pad of the display panel 110 in a tape automated bonding (TAB) type or a chip-on-glass (COG) type or can be disposed directly on the display panel 110.

In some situations, each source driving integrated circuit SDIC can be integrated and disposed on the display panel 110. Further, each source driving integrated circuit SDIC can be implemented in a chip-on-film (COF) type and, in this situation, each source driving integrated circuit SDIC can be mounted on a circuit film and can be electrically connected to the data line DL of the display panel 110 through the circuit film.

The controller 140 supplies various control signals to the gate driving circuit 120 and the data driving circuit 130 and controls the operation of the gate driving circuit 120 and the data driving circuit 130. In other words, the controller 140 can control the gate driving circuit 120 to output a scan signal according to the timing implemented in each frame and, on the other hand, transfers the image data DATA received from the outside to the data driving circuit 130.

In this situation, the controller 140 receives, from an external host system 200, several timing signals including, e.g., a vertical synchronization signal Vsync, a horizontal synchronization signal Hsync, a data enable signal DE, and a main clock MCLK, together with the image data DATA.

The host system 200 can be any one of a television (TV) system, a set-top box, a navigation system, a personal computer (PC), a home theater system, a mobile device, and a wearable device.

Accordingly, the controller 140 can generate a control signal according to various timing signals received from the host system 200 and transfers the control signal to the gate driving circuit 120 and the data driving circuit 130.

For example, the controller 140 can output several gate control signals including, e.g., a gate start pulse GSP, a gate clock GCLK, and a gate output enable signal GOE, to control the gate driving circuit 120. The gate start pulse GSP controls the timing at which one or more gate driving integrated circuits GDIC constituting the gate driving circuit 120 start operation. The gate clock GCLK is a clock signal commonly input to one or more gate driving integrated circuits GDIC and controls the shift timing of the scan signal. The gate output enable signal GOE designates timing information about one or more gate driving integrated circuits GDICs.

The controller 140 can output various data control signals including, e.g., a source start pulse SSP, a source sampling clock SCLK, and a source output enable signal SOE, to control the data driving circuit 130. The source start pulse SSP controls the timing at which one or more source driving integrated circuits SDIC constituting the data driving circuit 130 start data sampling. The source sampling clock SCLK is a clock signal that controls the timing of sampling data in the source driving integrated circuit SDIC. The source output enable signal SOE controls the output timing of the data driving circuit 130.

The display device 100 can further include a power management circuit 150 that supplies various voltages or currents to, e.g., the display panel 110, the gate driving circuit 120, and the data driving circuit 130 or controls various voltages or currents to be supplied.

The power management circuit 150 adjusts the direct current (DC) input voltage Vin supplied from the host system 200, generating power required to drive the display panel 110, the gate driving circuit 120, and the data driving circuit 130. The power management circuit 150 can be called a power management integrated circuit (PMIC).

In an embodiment, the subpixel SP is positioned at the intersection between the gate line GL and the data line DL, and a light emitting element can be disposed in each subpixel SP. For example, the organic light emitting diode display can include a light emitting element, such as an organic light emitting diode, in each subpixel SP and can display an image by controlling the current flowing to the light emitting element according to the data voltage.

The display device 100 can be one of various types of devices, such as liquid crystal displays, organic light emitting diode displays, or plasma display panels.

The display device 100 can be a vehicle display device installed in various places in the interior space of a vehicle. In an embodiment, the display device 100 can be disposed (installed) on at least a portion of the dashboard of a vehicle. The dashboard of the vehicle includes a component disposed in front of a front seats (e.g., driver's seat or passenger seat) of the vehicle. For example, a vehicle's dashboard can include an input component for manipulating various functions inside the vehicle (e.g., air conditioner, audio system, navigation system, infotainment system, etc.). Also, the display device 100 can be integrated in a rear view mirror, a side mirror, or in place of a mirror.

According to another embodiment, the display device 100 can be installed in an interior space (e.g., the ceiling of the vehicle or the back of the headrest of the driver's seat and/or the passenger seat, etc.) positioned behind the first row where the driver's seat and the passenger seat next to it are positioned.

FIG. 2 is a view schematically illustrating a configuration of a display device according to embodiments of the disclosure.

Referring to FIG. 2, in the display device 100 according to embodiments of the disclosure, the source driving integrated circuit SDIC included in the data driving circuit 130 and the gate driving integrated circuit GDIC included in the gate driving circuit 120 are implemented in the chip-on-film (COF) type among various types (e.g., TAB, COG, or COF).

One or more gate driving integrated circuits GDIC included in the gate driving circuit 120 each can be mounted on a gate film GF, and one side of the gate film GF can be electrically connected with the display panel 110. Lines for electrically connecting the gate driving integrated circuit GDIC and the display panel 110 can be disposed on the gate film GF.

The gate driving circuit 120 can be located only on one side of the display panel 110 or on each of two opposite sides according to driving methods. The gate driving circuit 120 can be implemented in a gate-in-panel GIP) form which is embedded in the bezel area of the display panel 110.

Likewise, one or more source driving integrated circuits SDIC included in the data driving circuit 130 each can be mounted on the source film SF, and one side of the source film SF can be electrically connected with the display panel 110. Lines for electrically connecting the source driving integrated circuit SDIC and the display panel 110 can be disposed on the source film SF.

The display device 100 can include a plurality of source driving integrated circuits SDIC and a printed circuit board for circuit connection between other devices. The printed circuit board can include, e.g., at least one source printed circuit board SPCB and a control printed circuit board CPCB for mounting control components and various electric devices.

In an embodiment, the other side of the source film SF where the source driving integrated circuit SDIC is mounted can be connected to at least one source printed circuit board SPCB. In other words, one side of the source film SF where the source driving integrated circuit SDIC is mounted can be electrically connected with the display panel 110, and the other side thereof can be electrically connected with the source printed circuit board SPCB.

The controller 140 and the power management circuit (power management IC) 150 can be mounted on the control printed circuit board CPCB. The controller 140 can control the operation of the data driving circuit 130 and the gate driving circuit 120. The power management circuit 150 can supply driving voltage or current to the display panel 110, the data driving circuit 130, and the gate driving circuit 120 and control the supplied voltage or current.

At least one source printed circuit board SPCB and control printed circuit board CPCB can be circuit-connected through at least one connection member. The connection member can include, e.g., a flexible printed circuit FPC or a flexible flat cable FFC. In this situation, the connection member connecting the at least one source printed circuit board SPCB and control printed circuit board CPCB can be varied depending on the size and type of the display device 100. The at least one source printed circuit board SPCB and control printed circuit board CPCB can be integrated into a single printed circuit board.

In the so-configured display device 100, the power management circuit 150 transfers a driving voltage used for display driving or characteristic value sensing to the source printed circuit board SPCB through the flexible printed circuit FPC or flexible flat cable FFC. The driving voltage transferred to the source printed circuit board SPCB is supplied to emit light or sense a specific subpixel SP in the display panel 110 through the source driving integrated circuit SDIC.

FIG. 3 is a view illustrating a display device according to embodiments of the disclosure. FIG. 3 is a view illustrating a display panel 310 (e.g., the display panel 110 of FIG. 2) and a printed circuit board 320 according to embodiments of the disclosure.

A display device can include a display panel 310 and a printed circuit board 320. The display panel 310 can be implemented in various shapes. For example, the display panel 310 can be implemented in an irregular shape that is longer at the bottom than at the top (e.g., a trapezoid shape having rounded corners). However, without limitations thereto, the display panel 310 can be implemented in a regular structure, such as a rectangle. The printed circuit board 320 can include the source printed circuit board SPCB of FIG. 2. For example, the printed circuit board 320 of FIG. 3 can conceptually represent a source printed circuit board, but is not limited thereto.

In an embodiment, the display panel 310 can have a curved shape. The display panel 310 can be curved so that its curvature changes based on a first inflection area 311 and a second inflection area 313. For example, the display panel 310 can include a first area 301, a second area 302, and a third area 303. The first area 301 and the third area 303 can have a first curvature and the second area 302 can have a second curvature. The first curvature can be larger than the second curvature.

In an embodiment, the curvature can be changed from the first curvature to the second curvature or from the second curvature to the first curvature based on the first inflection area 311 and the second inflection area 313. The first inflection area 311 can correspond to a boundary area between the first area 301 and the second area 302. The second inflection area 313 can correspond to a boundary area between the second area 302 and the third area 303.

As the display panel 310 is bent (or formed in a curved type), the first area 301 and the third area 303 can be closer to the user than the second area 302.

However, without limitations thereto, the display panel 310 can be formed to have a specific curvature according to an embodiment. For example, the entire area of the display panel 310 can be formed to have a constant curvature.

In an embodiment, the display panel 310 can have a shape that is longer horizontally than vertically. For example, the display panel can have a horizontal length of 24 inches to 34 inches and a vertical length of 3 inches to 6 inches.

The printed circuit board 320 can be directly or indirectly connected to one side of the display panel 310. For example, the printed circuit board 320 can be connected to the lower side of the display panel 310, but embodiments are not limited thereto. For example, the printed circuit board 320 can be connected to the upper side of the display panel 310. The printed circuit board 320 and the display panel 310 can be connected directly or via another component. When the printed circuit board 320 is directly or indirectly connected to one side of the display panel 310, this can mean that the printed circuit board 320 is directly connected to the side of the display panel 310 (direct connection), or the printed circuit board 320 can be connected to the side of the display panel 310 via another component (e.g., the source film SF of FIG. 2) (indirect connection).

For example, a source film can be disposed between the display panel 310 and the printed circuit board 320. The printed circuit board 320 can be connected to the display panel 310 through the source film. A source driving integrated circuit (e.g., the source driving integrated circuit SDIC of FIG. 2) can be disposed on the source film. The source film can be formed of a flexible material. In this situation, at least a portion of the source film can be bent behind the display panel 310. The printed circuit board 320 can be disposed on the rear surface of the display panel 310 based on at least a portion of the source film being bent.

The printed circuit board 320 can include an elastic member, a supporting member, and a metal layer.

In an embodiment, the elastic member can be disposed in at least a partial area of the printed circuit board 320. The elastic member can include an elastomer. For example, the elastic member can include at least one of silicone rubber and polyurethane. The elastic member can be formed of a material having an elastic modulus in a predetermined range. For example, the elastic member can be configured to have an elastic modulus in the range of 0.00005 GPa or more and 0.004 GPa or less. The elastic member can maintain elasticity at a temperature above −40° C. and below 95° C.

The area where the elastic member is disposed can be referred to as an elastic area. The elastic member can be disposed in each of a plurality of elastic areas. For example, the elastic member can be disposed in each of a first elastic area 321 and a second elastic area 323 of the printed circuit board 320.

In an embodiment, the elastic area can correspond to an inflection area of the display panel 310 (e.g., a bent portion or a creased portion, where an angle changes). For example, the first elastic area 321 can correspond to the first inflection area 311, and the second elastic area 323 can correspond to the second inflection area 313. For example, when the printed circuit board 320 is disposed on the rear surface of the display panel 310, the first elastic area 321 can be disposed to overlap with at least a portion of the first inflection area 311, and the second elastic area 323 can be disposed to overlap with at least a portion of the second inflection area 313.

Accordingly, even when the display panel 310 is stretched or contracted, the printed circuit board 320 can be effectively placed in tight contact with or adjacent to the rear surface of the display panel 310. In other words, even when the display panel 310 is deformed, e.g., stretched or contracted, lifting or peeling between the printed circuit board 320 and the display panel 310 can be minimized or prevented.

In an embodiment, the supporting member can be disposed on the same layer as the elastic member. The supporting member can include a plate having a certain hardness or higher. For example, the supporting member can be formed of a plastic material. The supporting member can have plasticity. The supporting member may not have elasticity. However, without limitations thereto, in some situations, the supporting member can have elasticity of a predetermined value or less. However, in this situation, the elasticity of the supporting member can be lower than that of the elastic member.

In an embodiment, the metal layer can include lines. In this situation, the metal layer can be disposed in various shapes at various positions on the printed circuit board 320 depending on the implementations (or shapes) of the lines. However, the metal layer can be disposed on a different layer than the elastic member and supporting member.

A more detailed description related to the elastic member, supporting member, and metal layer is made below with reference to FIG. 4.

During the manufacturing process of the display device, the display panel 310 and/or the printed circuit board 320 can be exposed to various environmental factors, such as heat, vibration, pressure, and/or moisture. In this situation, the display panel 310 and/or the printed circuit board 320 can undergo deformation, such as stretching or shrinkage. The deformation can change the design and size, causing the display panel 310 and the printed circuit board 320 to become misaligned from each other. If the display panel 310 and the printed circuit board 320 are misaligned, the connections between the components included in the display panel 310 and the printed circuit board 320 can be misaligned, causing defects.

However, although deformed, the printed circuit board 320 according to an embodiment of the disclosure can be restored to its original state by including an elastic member. For example, although the display panel 310 and/or the printed circuit board 320 is deformed, the length of the elastic member can be adjusted by applying tensile or compression pressure to two opposite sides of the printed circuit board 320, thereby fitting the size of the printed circuit board 320 to the display panel 310 and achieving an alignment.

According to an embodiment, when the display panel 310 is contracted or the printed circuit board 320 is stretched, compression pressure can be applied to the printed circuit board 320 to reduce the size (or horizontal length) of the printed circuit board 320. In this situation, the shape of the elastic member can be bent, and for the specific example related thereto, FIG. 10 can be referenced. If the display panel 310 is stretched or the printed circuit board 320 is contracted, a tensile pressure can be applied to the printed circuit board 320 to increase the size (or horizontal length) of the printed circuit board 320. In this situation, the shape of the elastic member can be bent. For example, as the thickness of at least a portion of the elastic member decreases, a bend can occur.

FIG. 3 illustrates an example in which one printed circuit board 320 is connected to one display panel 310, but is not limited thereto. A plurality of printed circuit boards 320 can be connected to one display panel 310. In such a situation, the spirit according to embodiments of the disclosure is not limited, and for a specific example related thereto, FIGS. 8 to 10 can be referenced.

FIG. 4 is a cross-sectional view taken along line A-A′ of FIG. 3 according to an embodiment of the disclosure.

Referring to FIG. 4, a printed circuit board (e.g., the printed circuit board 320 of FIG. 3) can include a plurality of layers. More specifically, a plurality of elastic members 401, 402, and 403 can be disposed in an elastic area (e.g., the first elastic area 321 of FIG. 3). The plurality of elastic members 401, 402, and 403 can be positioned on different layers of the printed circuit board. At least some of each of the plurality of elastic members 401, 402, and 403 can be disposed to overlap with each other. For example, as illustrated, the plurality of elastic members 401, 402, and 403 can be disposed to overlap with each other. Also, ends of the plurality of elastic members 401, 402, and 403 can be aligned with each other, but embodiments are not limited thereto. For example, according to an embodiment, the plurality of elastic members 401, 402, and 403 can have a staggered arrangement.

A plurality of supporting members 404, 406, and 408 can be disposed to correspond to the number of the plurality of elastic members 401, 402, and 403. For example, a first supporting member 404 can be disposed on the same layer as a first elastic member 401. A second supporting member 406 can be disposed on the same layer as a second elastic member 402. A third supporting member 408 can be disposed on the same layer as a third elastic member 403. The supporting members 404, 406, and 408 can be disposed in a flat shape around the plurality of elastic members 401, 402, and 403. The supporting members 404, 406, and 408 can maintain the shape of the printed circuit board and can support the plurality of elastic members 401, 402, and 403 and the metal layers 410, 412, and 414.

The metal layers 410, 412, and 414 can include a plurality of layers. The metal layers 410, 412, and 414 are components for forming lines and can be disposed in different shapes on the respective layers, but are not limited thereto. In some situations, at least some of the metal layers 410, 412, and 414 can have a form of jumping lines that pass through at least some of the supporting members 404, 406, and 408.

The metal layers 410, 412, and 414 can be disposed on layers different from those of the elastic members 401, 402, and 403 and/or the supporting members 404, 406, and 408. A layer on which the first elastic member 401 and the first supporting member 404 are disposed is referred to as a first layer (e.g., a first layer part), a layer on which the second elastic member 402 and the second supporting member 406 are disposed is referred to as a second layer (e.g., a second layer part), and a layer on which the third elastic member 403 and the third supporting member 408 are disposed is referred to as a third layer (e.g., a third layer part). In this situation, the first metal layer 410 can be disposed between the first layer and the second layer, and the second metal layer 412 can be disposed between the second layer and the third layer. The third metal layer 414 can be disposed on the third layer. Also, an additional elastic member and supporting member can be further disposed on the third metal layer 414 according to an embodiment.

The first metal layer 410 can be considered to be positioned between the first layer and the second layer, or can be considered to be included in the first layer. The second metal layer 412 can be considered to be positioned between the second layer and the third layer, or can be considered to be included in the second layer. The third metal layer 414 can be considered to be positioned on the third layer, or can be considered to be included in the third layer.

According to an embodiment, at least some of the metal layers 410, 412, and 414 can overlap with the elastic members 401, 402, and 403, but are not limited thereto. For example, some metal layers can overlap with the elastic members 401, 402, and 403, while other metal layers may not overlap with the elastic members 401, 402, and 403.

In an embodiment, the metal layers 410, 412, and 414 can include at least one hole. At least one hole can be disposed in an area different from an area overlapping with the plurality of elastic members 401, 402, and 403. At least one hole can be disposed not to overlap with the plurality of elastic members 401, 402, and 403. For example, the metal layers 410, 412, and 414 can include at least one hole that is spaced apart from each of the plurality of elastic members 401, 402, and 403.

In an embodiment, at least two or more of the holes included in the plurality of metal layers 410, 412, and 414, respectively, may not overlap with each other. For example, the first hole 421 included in the first metal layer 410 and the second hole 422 included in the second metal layer 412 may not overlap with each other. The second hole 422 included in the second metal layer 412 and the third hole 423 included in the third metal layer 414 may not overlap with each other.

In an embodiment, at least two of the holes included in the plurality of metal layers 410, 412, and 414, respectively, can overlap with each other. For example, the first hole 421 included in the first metal layer 410 and the third hole 423 included in the third metal layer 414 can overlap with each other. Also, the centers of at least two of the holes included in the plurality of metal layers 410, 412, and 414 can be aligned with each other, but embodiments are not limited thereto.

In an embodiment, the first hole 421 can be disposed in an area corresponding to a first side (e.g., or one side) of the plurality of elastic members 401, 402, and 403. The second hole 422 can be disposed in an area corresponding to a second side (e.g., or another side) of the plurality of elastic members 401, 402, and 403. However, the disclosure is not limited thereto.

FIG. 4 illustrates an example in which one hole is included in each of the metal layers 410, 412, and 414, but is not limited thereto. According to an embodiment, at least some of the metal layers 410, 412, and 414 can include two or more holes.

According to an embodiment, since holes are included in each of the metal layers 410, 412, and 414, deformation occurring in the metal layers 410, 412, and 414 as pressure is applied to the printed circuit board can be minimized. For example, when compression pressure is applied to two opposite sides of the printed circuit board, the size of the hole can decrease as the surrounding metal layer fills the hole. In this situation, the size of the hole can be changed, but the shape change or bending of the metal layers 410, 412, and 414 can be minimized. In other words, the holes in each of the metal layers 410, 412, and 414 can provided relief areas or expansion areas so that when the metal layers 410, 412, and 414 are heated, cooled or vibrated, they have some room to expand and contract without cracking or causing permanent damage, and the plurality of elastic members 401, 402, and 403 can return the metal layers 410, 412, and 414 back to their original positions once the environmental conditions have normalized.

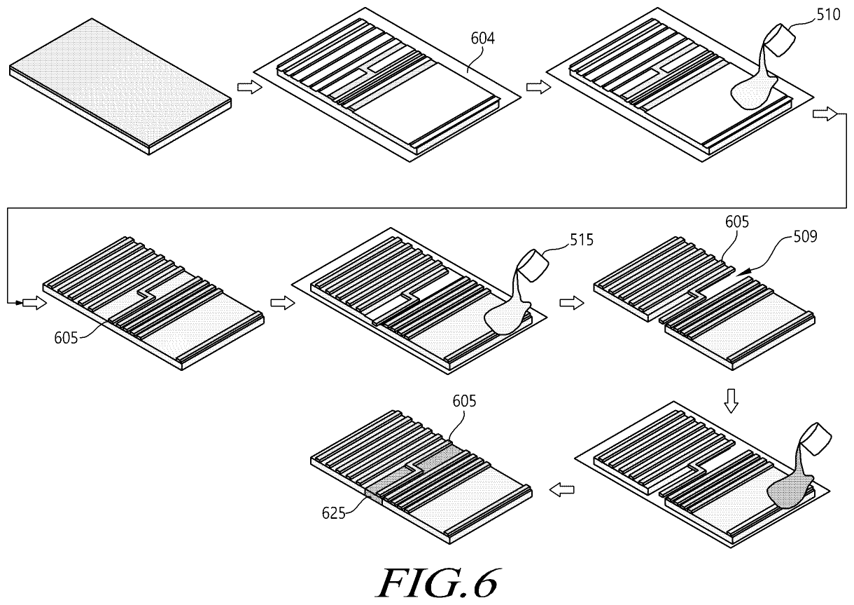

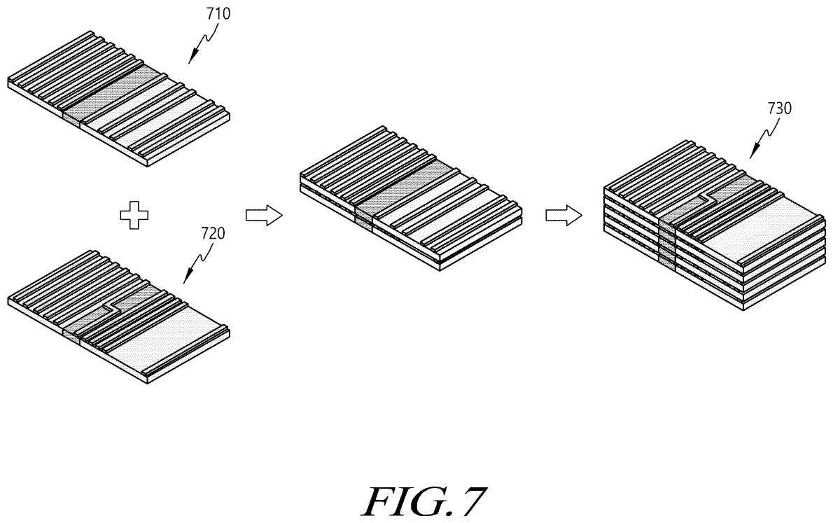

FIGS. 5, 6, and 7 are views illustrating an example method for manufacturing a printed circuit board included in a display device according to embodiments of the disclosure. FIG. 5 illustrates an example method for manufacturing a first set including a first layer including an elastic member and a supporting member constituting a printed circuit board and a first metal layer on the first layer. FIG. 6 illustrates an example method for manufacturing a second set distinguished from the first set. FIG. 7 illustrates an example process for generating a printed circuit board by coupling the first set and the second set together.

Referring to FIG. 5, a metal plate 502 can be disposed on a supporting member 501. A first etching mask 504 for implementing the shape of the metal layer 505 can be seated on the metal plate 502. The first etching mask 504 can have a pattern corresponding to the metal layer 505. A first etching solution 510 for etching a metal material can be distributed on the first etching mask 504, and thus etching can be performed. Accordingly, a portion of the metal plate 502 can be etched away, forming the metal layer 505. The metal layer 505 is a component constituting lines and can be shaped according to a predetermined design. FIG. 5 illustrates a metal layer 505 shaped as a straight line. However, without limitations thereto, the metal layer 505 can be formed in other various shapes.

After the metal layer 505 is formed, the first etching mask 504 can be removed, and a second etching mask 507 can be seated on the metal layer 505. The second etching mask 507 can be configured to provide a space in which the elastic member 525 is to be disposed by etching away at least a portion of the supporting member 501 (e.g., creating a hole in 501). A second etching solution 515 for etching the supporting member 501 can be distributed on the second etching mask 507. The second etching solution 515 is a solution for etching the material constituting the supporting member 501, and can be a solution different from the first etching solution. At least a portion of the supporting member 501 can be etched away by the second etching solution 515 (e.g., creating a hole for placing an elastic member). Accordingly, an elastic area 509 (e.g., hole) in which the elastic member 525 is to be disposed can be provided.

If the elastic area 509 is provided, the second etching mask 507 can be removed, and a mask 521 covering the other portion except for the elastic area 509 can be disposed on the metal layer 505 for creating an elastic member 525. The mask 521 for the elastic member can have an open portion corresponding to the elastic area 509. An elastic solution 517 can be distributed on the mask 521 for the elastic member. The elastic solution 517 can harden in the elastic area 509, forming the elastic member 525.

FIG. 5 illustrates an example in which a metal layer is not disposed on the elastic member 525. The following embodiment of FIG. 6 represents an example which has the same set forming process as that of FIG. 5 except that a metal layer 605 is disposed on the elastic member 525.

Specifically, referring to FIG. 6, the first etching mask 604 of FIG. 6 can have a pattern different from that of the etching mask 504 of FIG. 5. A portion of the first etching mask 604 corresponding to the elastic area 509 can be open. Accordingly, the second etching solution 515 can etch away a portion of the supporting member to create the open area for placing the supporting member. Meanwhile, the disposition of the metal layer 605 can be maintained on the elastic area 509. As at least a portion of the metal layer 605 disposed on the elastic area 509 is connected to the metal layer 605 disposed on another area, the position and shape thereof can be maintained even on the elastic area 509. Also, the metal layer 605 can have a zigzag portion that extends or bridges across at least part of elastic area 509, but embodiments are not limited thereto.

Thereafter, the elastic member 625 can be provided in the elastic area 509 using a mask for an elastic member and an elastic solution. In some situations, an elastic solution can be disposed on at least a portion of the metal layer 605 disposed on the elastic area 509, but the elastic solution remaining on the metal layer 605 can be removed by a cleaning process.

Referring to FIG. 7, the first set 710 generated according to FIG. 5 and the second set 720 generated according to FIG. 6 can be stacked on top of each other. For example, the first set 710 can be stacked on the second set 720. As another example, the second set 720 can be stacked on the first set 710.

The manufacturing process according to FIG. 5 or 6 can be performed in a different order or regardless of order. Further, according to an embodiment, the manufacturing process according to FIG. 5 or FIG. 6 can be repeatedly performed. In this situation, an additional set can be generated, and the generated set can be stacked with the first set 710 and/or the second set 720, and thus the printed circuit board 730 can be formed, which can have multiple layers.

FIG. 8 is a view illustrating a display device according to another embodiment of the disclosure. FIG. 8 illustrates a situation in which a plurality of printed circuit boards 801 and 802 are connected to a display panel 810.

Referring to FIG. 8, the shape of the corner of the display panel 810 can be bent, and the shape of one side of the display panel 810 and the shape of the other side opposite thereto can be implemented to differ from each other. For example, the width of one side of the display panel 810 can be shorter than the width of the other side of the display panel 810.

The display panel 810 can have a bent shape, although not specifically revealed in FIG. 8 which is a plan view of the display panel 810. For example, the display panel 810 can have a shape in which each of the upper, lower, left, and right corners is bent to be adjacent to (or closer to) the user compared to the central portion when the user looks at the display panel 810 from the front. For the bent shape, FIG. 9 can be referenced.

According to an embodiment, the degree to which the display panel 810 is bent can differ according to each area. For example, the curvatures of the left and right sides of the display panel 810 can be different from each other based on the first inflection area 811 and/or the second inflection area 812.

A plurality of printed circuit boards 801 and 802 can be connected to the display panel 810. The plurality of printed circuit boards 801 and 802 can include a first printed circuit board 801 and a second printed circuit board 802. The first printed circuit board 801 can include a first elastic area 821 corresponding to the first inflection area 811 of the display panel 810. The second printed circuit board 802 can include a second elastic area 822 corresponding to the second inflection area 812 of the display panel 810.

For example, when the first printed circuit board 801 is disposed on a rear surface of the display panel 810, at least a portion of the first elastic area 821 can overlap with at least a portion of the first inflection area 811 of the display panel. When the second printed circuit board 802 is disposed on the rear surface of the display panel 810, at least a portion of the second elastic area 822 can overlap with at least a portion of the second inflection area 812 of the display panel.

In an embodiment, the first printed circuit board 801 can be disposed to be symmetrical to the second printed circuit board 802. However, the disclosure is not limited thereto.

Also, in an embodiment, the printed circuit boards 801 and 802 can be connected to other printed circuit boards. For example, when the printed circuit boards 801 and 802 include a source printed circuit board, each of the printed circuit boards 801 and 802 can be connected to a control printed circuit board. When there is one control printed circuit board, each of the printed circuit boards 801 and 802 can be connected to the control printed circuit board.

FIG. 9 is a cross-sectional view taken along line B-B′ of FIG. 8 according to an embodiment of the disclosure. FIG. 9 is a cross-sectional view illustrating an example in which the display panel and the printed circuit board are aligned by applying a pressure of compression to the printed circuit board as the display panel is contracted or the printed circuit board is stretched.

Referring to FIG. 9, the first printed circuit board 801 and the second printed circuit board 802 can be connected to the control printed circuit board 905. The control printed circuit board 905 can be disposed to overlap with the first printed circuit board 801 and the second printed circuit board 802, but is not limited thereto. A set cover 910 can be disposed to cover the first printed circuit board 801, the second printed circuit board 802, and the control printed circuit board 905. The set cover 910 can protect the first printed circuit board 801, the second printed circuit board 802, and the control printed circuit board 905.

According to an embodiment, when stretching occurs, contraction pressure can be applied to two opposite sides of the first printed circuit board 801 and the second printed circuit board 802, so that the first printed circuit board 801 and the second printed circuit board 802 can be changed to have the width before being stretched or the width at which they are aligned with the display panel. Further, since the elastic members included in the first printed circuit board 801 and the second printed circuit board 802, respectively, have a flexible property, the elastic members can more easily come into tight contact with the display panel 810.

For example, as illustrated, at one end 915 of the display panel 810, the first printed circuit board 801 can tightly contact the display panel 810.

In an embodiment, an aluminum plate can be disposed on the rear surface of the display panel 810. In this situation, the first printed circuit board 801 and the second printed circuit board 802 can be disposed to contact the aluminum plate.

In an embodiment, as the display panel 810 has a bent shape, a cross section of the display panel 810 can be shown as having a bent shape as illustrated in FIG. 9.

FIG. 10 is a cross-sectional view taken along line C-C′ of FIG. 8 according to an embodiment of the disclosure.

Referring to FIG. 10, as the pressure F of compression is applied to the first printed circuit board 801, a bent area 1010 can be formed in the elastic member 1017. The bent area 1010 can be implemented in an upward convex shape as illustrated, but is not limited thereto. For example, the elastic members 1017 in the bent area 1010 can allow for expansion and contraction movements without damaging the metal layers 1011.

In an embodiment, at least a portion of the metal layer 1011 can be disposed in the elastic area 821. For example, as at least a portion of the metal layer 1011 is disposed in the elastic area 821 in which the elastic member 1017 is disposed, the metal layer 1011 can be bent in response to a change in the shape of the elastic member 1017.

Components disposed outside the elastic area 821 can have a flat shape. For example, the supporting member 1015 disposed around the elastic area 821 can have a flat shape. The flat shape can mean an evenly flat shape without a higher or lower portion. However, without limitations thereto, it should be noted that it can include a bend within the tolerance range of the process.

The above-described display device according to an embodiment of the disclosure are briefly described again below.

A display device according to an embodiment of the disclosure can include a display panel and a printed circuit board connected directly or indirectly to the display panel and including a first layer part and a second layer part on the first layer part.

The first layer part can include a plurality of first supporting members spaced apart from each other, a first elastic member positioned between the plurality of first supporting members, and a first metal layer on the plurality of first supporting members and the first elastic member.

The second layer part can include a plurality of second supporting members spaced apart from each other, a second elastic member positioned between the plurality of second supporting members, and a second metal layer on the plurality of second supporting members and the second elastic member.

The first elastic member and the second elastic member can overlap with each other.

The first metal layer can include at least one first hole, and the second metal layer can include at least one second hole.

The at least one first hole may not overlap with the first elastic member and the second elastic member, and can overlap with at least one of the plurality of first supporting members and at least one of the plurality of second supporting members.

The at least one second hole may not overlap with the first elastic member and the second elastic member, and can overlap with at least one of the plurality of first supporting members and at least one of the plurality of second supporting members.

The at least one first hole can overlap with the second metal layer, and the at least one second hole can overlap with the first metal layer.

The at least one first hole and the at least one second hole may not overlap with each other.

The first metal layer can include a first portion positioned on one side of one first hole and a second portion positioned on another side of the one first hole, and the second metal layer can include a third portion positioned on one side of one second hole and a fourth portion positioned on another side of the one second hole.

One of the first portion and the second portion can have a different shape or bend from a rest thereof, or one of the third portion and the fourth portion can have a different shape or bend from a rest thereof.

The printed circuit board can be connected to a partial area of a substrate of the display panel or be connected to a connection member (e.g., a source film) connected to a partial area of the substrate. Accordingly, the printed circuit board can be positioned toward a rear surface (a surface opposite to the viewing surface) of the display panel.

The display device according to embodiments of the disclosure can be implemented as various types of display devices. For example, the display device according to embodiments of the disclosure can be a mobile display device, such as a smartphone or a tablet, a display device, such as a monitor or a television, or a vehicle display device installed in an interior space of a vehicle.

Although the embodiments of the disclosure have been described in more detail with reference to the accompanying drawings, the disclosure is not necessarily limited to these embodiments, and can be variously modified without departing from the technical spirit of the disclosure. Accordingly, the embodiments set forth herein are provided for illustrative purposes, but not to limit the scope of the disclosure, and should be appreciated that the scope of the disclosure is not limited by the embodiments. Thus, it should be noted that the above-described embodiments are provided as examples and should not be interpreted as limiting. The scope of the disclosure should be construed by the following claims, and all technical spirits within equivalents thereof should be interpreted to belong to the scope of the disclosure.

What is claimed:

1. A display device, comprising:
a display panel; and
a printed circuit board connected to the display panel,
wherein the printed circuit board includes:
a plurality of elastic members positioned on different layers, the plurality of elastic members overlapping with each other;
a plurality of supporting members disposed on same layers as the plurality of elastic members, respectively; and
a metal layer disposed on a different layer than the plurality of elastic members and the plurality of supporting members.

2. The display device of claim 1, further comprising a source film disposed between the display panel and the printed circuit board,
wherein the printed circuit board is connected to the display panel through the source film, and the printed circuit board is disposed on a rear surface of the display panel by bending the source film.

3. The display device of claim 1, wherein the metal layer includes at least one hole.

4. The display device of claim 3, wherein the metal layer includes a first metal layer and a second metal layer, and
wherein a first hole included in the first metal layer and a second hole included in the second metal layer do not overlap with each other.

5. The display device of claim 4, wherein the first hole included in the first metal layer is disposed in an area corresponding to a first side of the plurality of elastic members, and the second hole included in the second metal layer is disposed in an area corresponding to a second side of the plurality of elastic members.

6. The display device of claim 1, wherein a first area of the display panel has a first curvature, and a second area of the display panel has a second curvature different than the first curvature.

7. The display device of claim 6, wherein the plurality of elastic members are disposed in an area that corresponds to a boundary area between the first area of the display panel and the second area of the display panel.

8. The display device of claim 1, wherein the plurality of elastic members have a bend, and wherein the plurality of supporting members are flat.

9. The display device of claim 1, wherein the plurality of elastic members maintain elasticity at a temperature of about −40° C. to 95° C.

10. The display device of claim 1, wherein the plurality of elastic members have an elastic modulus of about 0.00005 GPa to 0.004 GPa.

11. The display device of claim 1, wherein the plurality of elastic members include an elastic polymer, and the plurality of supporting members include a plate with a hardness.

12. The display device of claim 1, wherein the plurality of elastic members include at least one of silicone rubber and polyurethane.

13. The display device of claim 1, wherein the display device is installed in an interior space of a vehicle.

14. A display device, comprising:
a display panel; and
a printed circuit board connected to the display panel, the printed circuit board including a first layer part and a second layer part disposed on the first layer part,
wherein the first layer part includes:
a plurality of first supporting members spaced apart from each other;
a first elastic member disposed between the plurality of first supporting members; and
a first metal layer disposed on the plurality of first supporting members and the first elastic member,
wherein the second layer part includes:
a plurality of second supporting members spaced apart from each other;
a second elastic member disposed between the plurality of second supporting members; and
a second metal layer disposed on the plurality of second supporting members and the second elastic member, and
wherein the first elastic member and the second elastic member overlap with each other.

15. The display device of claim 14, wherein the first metal layer includes a first hole, and the second metal layer includes a second hole.

16. The display device of claim 15, wherein the first hole overlaps with at least one of the plurality of first supporting members and at least one of the plurality of second supporting members, and
wherein the second hole overlaps with at least one of the plurality of first supporting members and at least one of the plurality of second supporting members.

17. The display device of claim 15, wherein the first hole and the second hole do not overlap with each other.

18. The display device of claim 14, wherein a spacing distance between the plurality of first supporting members is configured to change by elastic deformation of the first elastic member, and
wherein a spacing distance between the plurality of second supporting members is configured to change by elastic deformation of the second elastic member.

19. The display device of claim 14, wherein the printed circuit board is disposed at a rear surface of the display panel.

20. The display device of claim 14, wherein the display device is installed in an interior space of a vehicle.

21. A display device, comprising:
a display panel including a first display area, a second disposed area, and a first inflection area corresponding to a boundary between the first display area and the second display area;
a multi-layer printed circuit board electrically connected to the display panel,
wherein the multi-layer printed circuit board includes:
a first supporting member layer,
a first elastic member disposed between two portions of the first supporting member layer,
a first metal layer disposed on the first supporting member layer,
a second supporting member layer disposed on the first metal layer, and
a second elastic member disposed between two portions of the second supporting member layer, and
wherein the first and second elastic members overlap with the first inflection area.

22. The display device of claim 21, wherein the first display area has a first curvature, and the second display area has a second curvature different than the first curvature.

23. The display device of claim 21, further comprising:
a second metal layer disposed on the second supporting member layer,
wherein the first metal layer includes a first hole, and the first hole does not overlap with the first and second elastic members,
wherein the second metal layer includes a second hole, and the second hole does not overlap with the first and second elastic members, and
wherein the first and second holes are disposed on opposite sides of the first inflection area.

24. The display device of claim 21, wherein a portion of the first metal layer extends across the first elastic member, and
wherein the portion of the first metal layer includes a bent portion or a zigzag shape.
